(19) United States
(12) Patent Application Publication
(10) Pub. No.: US 2026/0305360 A1
(43) Pub. Date: Oct. 1, 2026

(54) BIDIRECTIONAL ELECTROSTATIC DISCHARGE DETECTOR

(71) Applicant: Micron Technology, Inc., Boise, ID (US)

(72) Inventors: James E. Davis, Meridian, ID (US); Kenneth W. Marr, Boise, ID (US); Wei Chang Wong, Singapore (SG); Tsung Che Tsai, Taichung (TW); Souvick Mitra, Boise, ID (US)

(21) Appl. No.: 19/578,023

(22) Filed: Mar. 25, 2026

Related U.S. Application Data
(60) Provisional application No. 63/779,502, filed on Mar. 28, 2025.

(51) Int. Cl. H10W 42/60; H02H 1/00; H10D 89/60

(52) U.S. Cl. CPC H10W 42/60; H02H 1/0007; H10D 89/611

(57) ABSTRACT

Apparatuses, systems, and methods for bidirectional electrostatic discharge detectors are described. An example apparatus includes a fuse coupled between a bidirectional electrostatic discharge (ESD) element and a wire bond of a semiconductor package. The fuse is configured to receive an ESD current generated between the wire bond and a material external to the semiconductor package, as well as blow in response to the ESD current exceeding a threshold current magnitude. The apparatus further includes a detector coupled to the bidirectional ESD element, wherein the detector is configured to determine a state of the fuse.

### PRIORITY INFORMATION

This application claims the benefit of U.S. Provisional Application Number 63/779,502, filed on Mar. 28, 2025, the contents of which are incorporated herein by reference.

### TECHNICAL FIELD

The present disclosure relates generally to semiconductor memory and methods, and more particularly, to apparatuses, systems, and methods for a bidirectional electrostatic discharge detector.

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes random access memory (RAM), dynamic random-access memory (DRAM), static random-access memory (SRAM), synchronous dynamic random-access memory (SDRAM), and thyristor random access memory (TRAM), among others. Non-volatile memory can provide persistent data by retaining stored data when not powered and can include NAND flash memory, NOR flash memory, and resistance variable memory such as phase change random access memory (PCRAM), resistive random-access memory (RRAM), and magnetoresistive random access memory (MRAM), such as spin torque transfer random access memory (STT RAM), among others.

Flash memory devices can include a charge storage structure, such as is included in floating gate flash devices and charge trap flash (CTF) devices, which may be utilized as non-volatile memory for a wide range of electronic applications. Flash memory devices may use a one-transistor memory cell that allows for high memory densities, high reliability, and low power consumption.

Memory cells in an array architecture can be programmed to a target state. For example, electric charge can be placed on or removed from the floating gate of a memory cell to put the cell into one of a number of data states. For example, a single level cell (SLC) can be programmed to one of two data states representing one of two units of data (e.g., 1 or 0). Multilevel memory cells (MLCs) can be programmed to one of more than two data states. For example, an MLC capable of storing two units of data can be programmed to one of four data states, an MLC capable of storing three units of data can be programmed to one of eight data states, and an MLC capable of storing four units of data can be programmed to one of sixteen data states. MLCs can allow the manufacture of higher density memories without increasing the number of memory cells since each cell can represent more than one unit of data (e.g., more than one bit). However, MLCs can present difficulties with respect to sensing operations as the ability to distinguish between adjacent data states may deteriorate over time and/or operation.

Electrostatic discharges (ESDs) can occur during the manufacturing of memory devices. An ESD can refer to a sudden flow of electricity between two electrically charged objects. The ESD can occur when contact or near contact occurs between the two electrically charged objects. The ESD can be a rapid transfer of charge that can potentially cause damage to components of the memory device.

### BRIEF DESCRIPTION OF THE DRAWINGS

The present disclosure will be understood more fully from the detailed description given below and from the accompanying drawings of various embodiments of the disclosure.

FIG. 1 is a prior art block diagram of a device to illustrate an electrostatic discharge (ESD) between a memory die and an external material.

FIGS. 2A-2B illustrate a bidirectional electrostatic discharge detector in accordance with some embodiments of the present disclosure.

FIG. 3A is a prior art system that utilizes ESD protection.

FIGS. 3B-3C illustrate examples of systems that utilize a bidirectional ESD detector in accordance with some embodiments of the present disclosure.

FIG. 4A illustrates a top-down view and a cross-sectional view of an internal metal fusing structure for integrating the bidirectional ESD detector in accordance with some embodiments of the present disclosure.

FIG. 4B illustrates a chart for contact resistance pass/fail requirements in accordance with some embodiments of the present disclosure.

FIG. 5 illustrates an example method for measuring an ESD using an ESD detector in accordance with some embodiments of the present disclosure.

### DETAILED DESCRIPTION

Aspects of the present disclosure are directed to a bidirectional electrostatic discharge detector. The bidirectional electrostatic discharge detector can be utilized to detect and determine that an electrostatic discharge has occurred in association with a bond contact coming into contact or nearly comes into contact with an external material. The bidirectional electrostatic discharge detector can detect electrostatic discharges while positioned on die.

An electrostatic discharge can refer to a sudden flow of electricity between two electrically charged objects caused by contact, an electrical short, and/or dielectric breakdown. The electrostatic discharge can occur in response to a difference in electrical potential between the two objects that is greater than a threshold current magnitude, which can lead to the rapid transfer of charge between the two objects. As described herein, electrostatic discharge can damage electronic components, particularly sensitive microelectronics, by causing electrical overstress. In industrial and electronics manufacturing settings, measures are taken to prevent electrostatic discharge to protect equipment and ensure safety.

Previous systems and methods may not be able to accurately detect the voltage caused by the electrostatic discharge and/or determine whether the voltage caused by the electrostatic discharge will damage the components of the memory die. If the voltage and/or current of the electrostatic discharge is not detected during the bonding operation, the resulting device may include damaged components within the memory die that are not identified. This can result in end products that have lower performance and/or non-functional components.

In order to address these and other deficiencies of current approaches, embodiments of the present disclosure can be used to monitor electrostatic discharges and determine whether the voltage and/or current of the electrostatic discharge exceeds a threshold current magnitude (e.g., threshold electrostatic discharge). In these embodiments, an electrostatic discharge detector can be utilized to determine whether an electrostatic discharge occurs, an amplitude of the voltage or current of the electrostatic discharge, and/or a contact on the memory die where the electrostatic discharge occurred. In some embodiments, this can be achieved utilizing an on-chip electrostatic discharge detector.

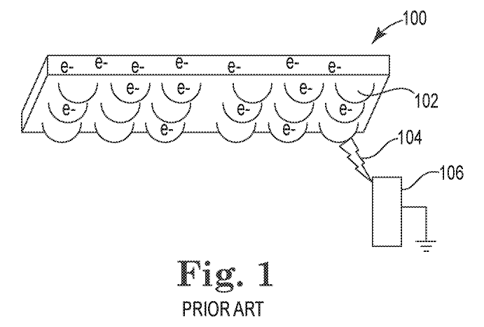

FIG. 1 is a prior art memory die package 100 to illustrate an electrostatic discharge (ESD) 104 between the memory die package 100 and an external material 106. More specifically, an electrostatic discharge 104 between a solder ball 102 of the memory die package 100 and the external material 106 can occur when the solder ball 102 and the external material 106 has a potential difference.

As used herein, the term “die package” refers to an enclosure that can hold one or more memory component. Those memory components can include, but are not limited to, memory chips and processors.

As used herein, the term “electrostatic discharge” refers to the rapid, spontaneous transfer of electrostatic charge induced by a high electrostatic field. The charge can flow through a spark between two conductive bodies at different electrostatic potentials as they approach one another. ESD can change the electrical characteristics of a semiconductor device, degrading or destroying it. ESD may also upset the normal operation of an electronic system, causing equipment malfunction or failure. Charged surfaces can attract and hold contaminants, making removal of the particles difficult. When attracted to the surface of a silicon wafer or a device's electrical circuitry, air-borne particulates can cause random wafer defects and reduce product yields.

Creating electrostatic charge by contact and separation of materials can be known as triboelectric charging. Triboelectric charging can involve the transfer of electrons between materials. The atoms of a material with no static charge can have an equal number of positive (+) protons in the nucleus and negative (-) electrons orbiting the nucleus. When the two materials are placed in contact and then separated, negatively charged electrons can be transferred from the surface of one material to the surface of the other material. Which material loses electrons and which gains electrons can depend on the nature of the two materials. The material that loses electrons can become positively charged, while the material that gains electrons can be negatively charged.

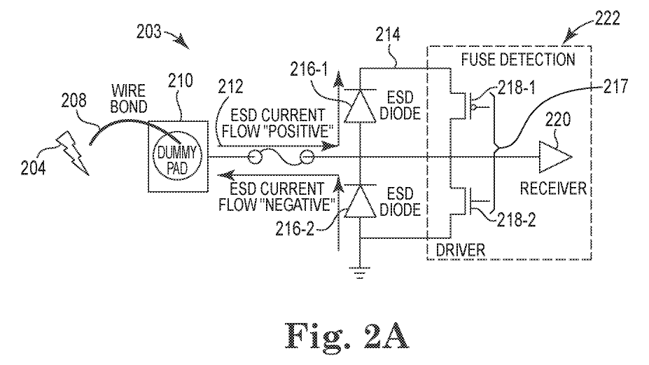

FIG. 2A illustrates a bidirectional ESD detector 203 in accordance with some embodiments of the present disclosure. The bidirectional ESD detector 203 can include a fuse 212 coupled between a bidirectional ESD element 214 and a wire bond 208 of a memory die package (e.g., memory die package 100 of FIG. 1). In some embodiments, the fuse 212 can be configured to receive an ESD current 204 generated between the wire bond 208 and a material (e.g., external material 106 in FIG. 1) external to the semiconductor package. In some embodiments, the wire bond 208 can be coupled to the fuse 212 by a dummy pad 210 of the memory package.

The fuse 212 can be configured to blow in response to the ESD current exceeding a threshold current magnitude. As used herein, a fuse 212 is considered “blown” when a current exceeding a threshold current magnitude passes through a certain material in the fuse 212 and melts that material. When a fuse 212 is blown, no current can travel through the fuse 212. If the fuse 212 is blown, this can indicate that the wire bond 208 has received a current exceeding the threshold current magnitude. The current exceeding the threshold current magnitude can be an ESD current.

In some embodiments, the bidirectional ESD element 214 can include a plurality of ESD diodes 216-1, 216-2 (individually or collectively referred to as ESD diodes 216). In some embodiments, a first ESD diode 216-1 of the plurality of ESD diodes 216 can be coupled to a first skewed driver 218-1 and a second ESD diode 216-2 of the plurality of ESD diodes. Further, the second ESD diode 216-2 can be coupled to the first ESD diode 216-1 and ground. In some embodiments, the first ESD diode 216-1 and the second ESD diode 216-2 can be coupled in series. Further, the polarity of the ESD current can determine which ESD diode 216 the ESD current flows through. For example, an ESD current with a negative polarity can flow from the second ESD diode 216-2 to the fuse 212, flow through the fuse 212, and then flow from the fuse 212 to the dummy pad 210. Alternatively, an ESD current with a positive polarity can flow from the dummy pad 210 to the fuse 212, through the fuse 212, and then flow from the fuse 212 to the first ESD diode 216-1.

The bidirectional ESD detector 203 can further include a fuse detector 222 coupled to the bidirectional ESD element 214, wherein the fuse detector 222 is configured to determine a state of the fuse 212. In some embodiments, the fuse detector 222 can include a first driver 218-1 and second driver 218-2 of a skewed driver 217. The skewed driver 217 can be a voltage driver that pulls voltage to one polarity stronger than it pulls voltage in the opposite polarity. In some embodiments, the term “voltage driver” refers to a memory component that drives current through a circuit. In some embodiments, the skewed driver 218 can be a weak pull-up and strong pull-down driver. In some embodiments, the skewed driver 218 can be a strong pull-up driver and weak pull-down driver.

The fuse detector 222 can also include a receiver 220. In some embodiments, the receiver 220 can be configured to receive current from the bidirectional ESD element 214. Further, the receiver 220 can be coupled to a memory component external to the bidirectional ESD detector 203.

FIG. 2B illustrates a bidirectional ESD detector 203 in accordance with some embodiments of the present disclosure. As stated in reference to FIG. 2A, the bidirectional ESD detector 203 in FIG. 2B can include a fuse 212 coupled between a bidirectional ESD element 214 and a wire bond 208 of a memory die package. In some embodiments, the fuse 212 can be configured to receive an ESD current 204 generated between the wire bond 208 and a material external to the semiconductor package. In some embodiments, the wire bond 208 can be coupled to the fuse 212 by a dummy pad 210 of the memory package.

In the embodiment illustrated in FIG. 2B, the ESD detector 203 can include ESD snapback elements 215-1 and 215-2 (individually or collectively referred to as ESD snapback elements 215) instead of the ESD diodes 216 illustrated in FIG. 2A. As used herein, the term “ESD snapback element” refers to a component that utilizes a mechanism in which an avalanche current flows to a transistor to cause the transistor to allow current to flow between a source and a drain of the transistor. Once this occurs, the strong electric field that caused the avalanche current is no longer necessary to sustain the avalanche current and the conduction of large currents continues even at lower voltages. As used herein, the term “avalanche current” refers to a large current that flows through a material when a voltage applied thereto exceeds the material’s breakdown voltage. In some embodiments, each ESD snapback element 215 can be a bi-polar junction transistor, silicon controlled rectifier (SCR), or other snapback elements.

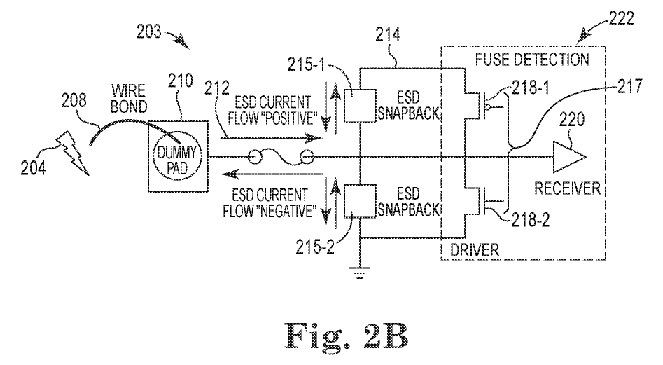

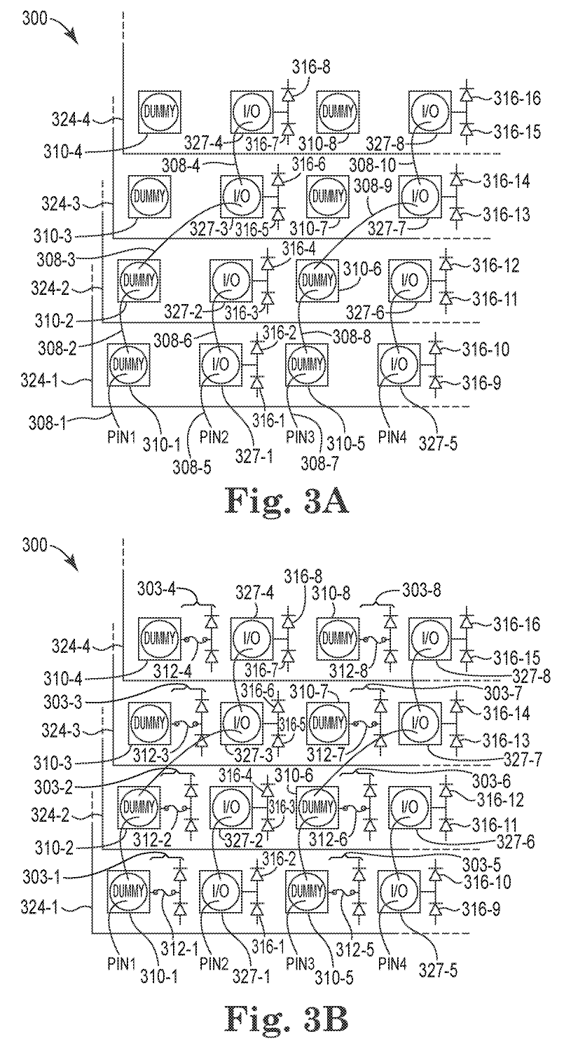

FIG. 3A is a prior art system that utilizes ESD protection. The prior art system can include a plurality of memory die 324-1, 324-2, 324-3, and 324-4 (individually or collectively referred to as memory die 324). Each memory die 324 can include a plurality of dummy pads 310-1, 310-2, . . ., and 310-8 (individually or collectively referred to as dummy pads 310), a plurality of input/output (I/O) pads 327-1, 327-2, . . ., 327-8 (individually or collectively referred to as I/O pads 327), and a plurality of ESD diodes 316-1, 316-2, . . ., 316-16 (individually or collectively referred to as ESD diodes 316) coupled to the I/O pads 327.

Current methods of ESD testing can include, but are not limited to, the Human Body Model and the Charged Device Model. The Human Body Model (HBM) establishes the procedure for testing, evaluating, and classifying components and microcircuits according to their susceptibility (sensitivity) to damage or degradation by exposure to a defined HBM ESD. The HBM is a simulation of the ESD which might occur when a human touches an electronic device. The purpose of the HBM standard is to establish a test method that will replicate HBM failures and provide reliable, repeatable HBM ESD test results from tester to tester, regardless of component type. Repeatable data will allow accurate classifications and comparisons of HBM ESD sensitivity levels.

A Charged Device Model (CDM) is an ESD test method used to evaluate the immunity of integrated circuits (ICs) or chips against ESD events that could occur during an IC’s automated manufacturing, handling, and assembly. In this test, test signals are applied to charge the IC, and then the IC is discharged to a metal ground plane to simulate the ESD event. This test assesses whether the device under test (DUT) has sufficient immunity against ESD. The purpose of CDM ESD immunity testing is to ensure that the IC or chip can withstand ESD events during its manufacturing and handling processes and meet the effectiveness and reliability requirements described by ESD test standards.

FIG. 3B illustrates an example of a system that utilize a bidirectional ESD detector in accordance with some embodiments of the present disclosure. In some embodiments, the system can be a semiconductor package 300 that includes a plurality of I/O pads 327 each coupled to a respective memory device (not pictured). The semiconductor package 300 can further include a plurality of dummy pads 310, a plurality of first bidirectional ESD detectors 303-1, 303-2, . . ., and 303-4 and a plurality of second bidirectional ESD detectors 303-5, . . ., and 303-8. In some embodiments, bidirectional ESD detectors 303-2 and 303-4 can be coupled to a respective I/O pad 327 via respective dummy pads 310. Further, in some embodiments, each second bidirectional ESD detector 303-1 and 303-5 can be coupled to a respective dummy pad 310 of the plurality of dummy pads 310 and configured to detect an ESD event associated with the respective dummy pad 310 and a material (e.g., material 106 in FIG. 1) external to the respective dummy pad 310.

In some embodiments, bidirectional ESD detectors 303-1 and 303-5 can comprise respective fuses 312-1 and 312-5 coupled between a bidirectional ESD element (e.g., bidirectional ESD element 214 in FIG. 2) and a respective dummy pad 310-1 and 310-5. In some embodiments, the respective fuse 312-1 and 312-5 can be configured to receive an ESD current (e.g., ESD 104 current in FIG. 1) generated between a wire bond (e.g., wire bond 208 in FIG. 2) coupled to the respective dummy pad 310-1 and 310-5 and the material external to the semiconductor package. In some embodiments, a respective fuse 312-1 and 312-5 can be configured to blow in response to the ESD discharge current exceeding a threshold current magnitude and a respective fuse detector coupled to the bidirectional ESD element can be configured to determine a state of the respective fuse 312-1 and 312-5. In some embodiments, the respective fuse detector can be configured to indicate a pass signal to a testing device (not pictured) in response to the respective fuse 312-1 and 312-5 being intact and indicate a fail signal to the testing device in response to the respective fuse 312-1 and 312-5 being blown.

In some embodiments, the plurality of I/O pads 327, the plurality of dummy pads 310, and the plurality of bidirectional ESD detectors 303 can be formed on a plurality of memory dies 324. Further, each memory die 324 of the plurality of memory dies 324 can include more than one dummy pad 310 and more than one I/O pad 327. In some embodiments, the first memory die 324-1 of the plurality of memory dies 324 can include a first dummy pad 310-1 coupled to a first pinout (pin 1) from the semiconductor package 300 and a first I/O pad 327-1 coupled to a second pinout from the semiconductor package 300. A second memory die 324-2 of the plurality of memory die 324 can include a second dummy pad 310-2 coupled to the first dummy pad 310-1 via a wire bond 308-2 and a second I/O pad 327-2 coupled to the first I/O pad 327-1 via a wire bond 308-b. Further, a third memory die 324-3 of the plurality of memory dies 324 can include a third I/O pad 327-3 coupled to the second dummy pad 310-2 via a third wire bond 308-3.

In some embodiments, the semiconductor package 300 can be configured to transfer data from a third I/O pad 327-3 to the first pinout (pin 1) via the first dummy pad 310-1 and the second dummy pad 310-2. Further, the semiconductor package 300 can be configured to transfer data from the first I/O pad 327-1 and the second I/O pad 327-2 via the second pinout (pin 2). In some embodiments, a first memory die 324-1 of a plurality of memory dies 324 includes a first dummy pad 310-1 coupled to a first pinout (pin 1) from the semiconductor package 300 and a first I/O pad 327-1. A second memory die 324-2 of the plurality of memory dies 324 can include a second dummy pad 310-2 coupled to the first dummy pad 310-1 via a wire bond 308-2, and I/O pads 327-2, 327-6.

FIG. 3C illustrates another example of a system that utilize a bidirectional ESD detector 303 in accordance with some embodiments of the present disclosure. In some embodiments, a first memory die 324-1 can include a first dummy pad 310-1 coupled to a pinout (pin 1) from the semiconductor package 300 and a first I/O pad 327-1. The second memory die 324-2 can include a second dummy pad 310-2 coupled to the first dummy pad 310-1 via a second wire bond 308-2, and a second I/O pad 327-2. Further, a third memory die 324-3 can include a third dummy pad 310-3 coupled to the second dummy pad 310-2 via wire bond 308-3, and a third I/O pad 327-3, and a fourth memory die 324-2 can include a fourth dummy pad 310-4 coupled to the third dummy pad 310-3 via wire bond 308-4, and a fourth I/O pad 327-4.

Further, the first memory die 324-1 can include a dummy pad 310-5 coupled to a pinout (pin 3). In some embodiments, the second memory die 324-2 can include a dummy pad 310-6 coupled to dummy pad 310-5 via wire bond 308-6, the third memory die 324-3 can include a dummy pad 310-7 coupled to dummy pad 310-6 via wire bond 308-7, and the fourth memory die 324-4 can include a dummy pad 310-8 coupled to dummy pad 310-7 via wire bond 308-8.

In the embodiment shown in FIG. 3C, the semiconductor package 300 can comprise an engineering evaluation tool without functional data transfer from the I/O pads 328. In some embodiments, each bidirectional ESD detector 303 on the first memory die 324-1 can be configured to detect an ESD event in response to an ESD discharge current exceeding a threshold current magnitude. Further, each bidirectional ESD detector 303 on the second memory die 324-2 can be configured to detect an ESD event with twice the threshold current magnitude in response to the ESD current exceeding twice the threshold current magnitude. Further, each bidirectional ESD detector 303 on the third memory die 324-3 can be configured to detect a triple ESD event in response to the ESD current exceeding three times the threshold current magnitude and each bidirectional ESD detector 303 on the fourth memory die 324-4 can be configured to detect a quadruple ESD event in response to the ESD current exceeding four times the threshold current magnitude.

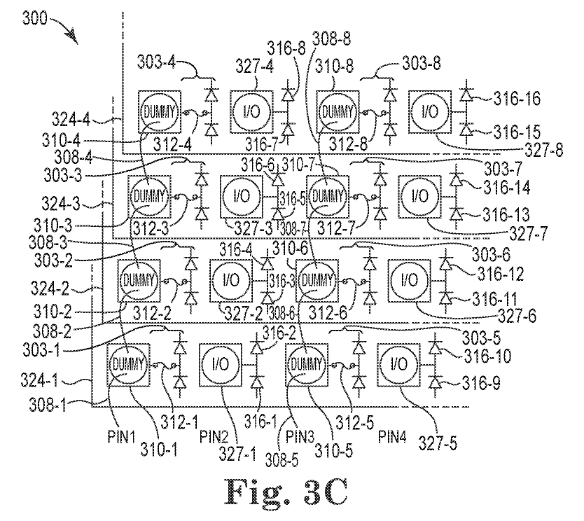

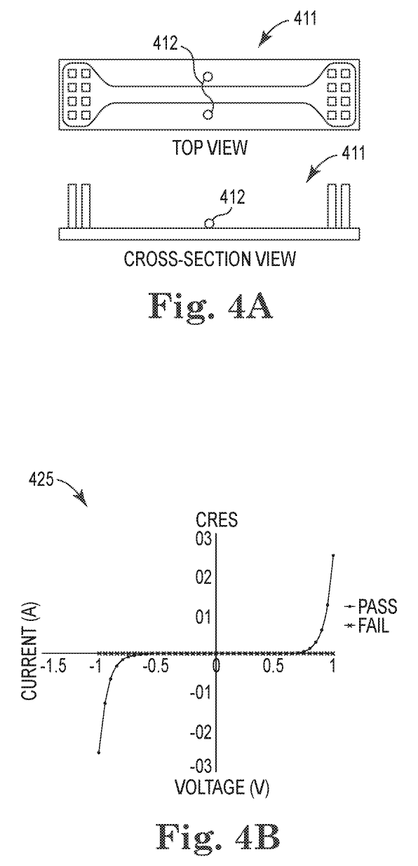

FIG. 4A illustrates a top view and a cross-sectional view of an internal metal fusing structure 411 for integrating the bidirectional ESD detector in accordance with some embodiments of the present disclosure. The internal fusing structure 411 can include a fuse 412 that can be calibrated from internal peak current testing. As used herein, the term “calibrated” can refer to configuring the fuse 412 to be able to receive a current of a specific magnitude without being blown. In some embodiments, after the fuse 412 is calibrated, it can be placed in the internal fusing structure 411. Further, in some embodiments, once the fuse 412 is placed in the internal fusing structure 411, the fuse 412 can be coupled to a dummy pad (e.g., dummy pad 210 in FIG. 2) and a bidirectional ESD element (e.g., bidirectional ESD element 214 in FIG. 2) of a bidirectional ESD detector (e.g., bidirectional ESD detector 203 in FIG. 2).

FIG. 4B illustrates a chart for contact resistance pass/fail requirements in accordance with some embodiments of the present disclosure. Failures are indicated where the contact resistance is essentially zero, which occurs in this example for currents between about -1.0 and 1.0 amperes. Passes are indicated as the contact resistance increases exponentially from about -0.5 to about -1.0 volts and from about 0.5 volts to about 1.0 volts.

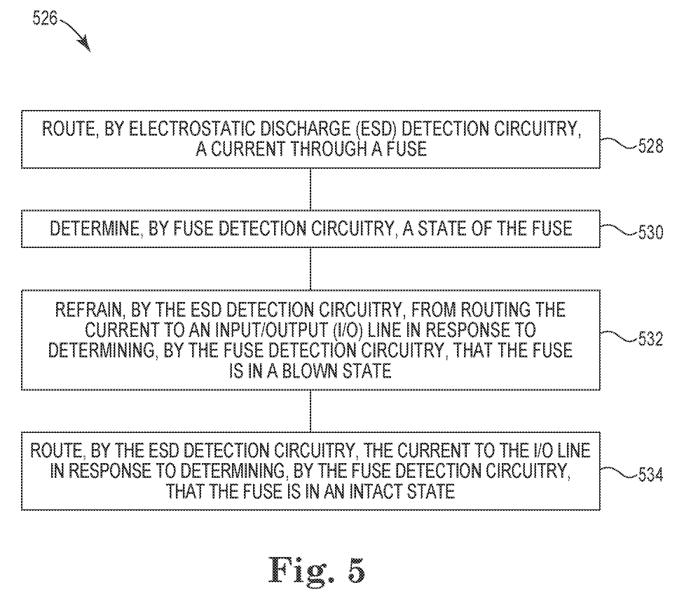

FIG. 5 illustrates an example method for measuring an ESD using an ESD detector in accordance with some embodiments of the present disclosure. The method 526 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 526 is performed by the bidirectional ESD detector 203 in FIG. 2. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At step 528, the method 526 can include routing, by ESD detection circuitry, a current through a fuse. In some embodiments, as shown in FIG. 3B-3C, current can be received through an I/O pin coupled to a dummy pad (e.g., dummy pad 310 in FIGS. 3B-3C). A fuse (e.g., fuse 312 in FIGS. 3B-3C) can be coupled to the dummy pad and receive the current via the dummy pad. In some embodiments, a memory die can include more than one dummy pad. In these embodiments, a first dummy pad of a memory die can receive a first current from a first I/O pin and a second dummy pad of the memory die can receive a second current from a second I/O pin. In some embodiments, the first dummy pad can receive the first current and the second dummy pad can receive the second current simultaneously.

At step 530, the method 526 can include determining, by fuse detection circuitry, a state of a fuse. As stated in regard to FIG. 3B, a fuse can be in an intact state or a blown state. A fuse can be in an intact state if the fuse has not received a current that exceeds a threshold current magnitude, and a fuse can be in a blown state if the fuse does receive a current that exceeds a threshold current magnitude. A fuse can include a ribbon (e.g., wire) through which current travels through the fuse. When a fuse receives a current that exceeds the threshold current magnitude, the current can damage (e.g., burn and/or melt) the ribbon. Once the ribbon is damaged, current may no longer be able to travel through the ribbon. The fuse can be in a blown state once the ribbon is damaged as described.

At step 532, the method 526 can include refraining, by the ESD detection circuitry, from routing the current to an I/O line in response to determining, by the fuse detection circuitry, that the fuse is in a blown state. As stated above, a fuse can be in a blown state when a ribbon included in the fuse is damaged such that a current can no longer travel through the ribbon. Further, in some embodiments, refraining from routing a current to an I/O line can prevent ESD current from moving to memory components external to the ESD detector and causing further damage to the memory device.

At step 534, the method 526 can include routing, by the ESD detection circuitry, the current to the I/O line in response to determining, by the fuse detection circuitry, that the fuse is in an intact state. The ESD detection circuitry can include fuse detection circuitry configured to detect whether the fuse is in an intact state. The fuse detection circuitry can also include a receiver configured to receive a current via the fuse. If the fuse detection circuitry within the ESD detection circuitry determines that the fuse is in an intact state, the current can be sent from the receiver to circuitry external to the fuse detection circuitry.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. An apparatus, comprising:
a fuse coupled between a bidirectional electrostatic discharge (ESD) element and a wire bond of a semiconductor package, wherein the fuse is configured to receive an ESD discharge current generated between the wire bond and a material external to the semiconductor package, wherein the fuse is configured to blow in response to the ESD discharge current exceeding a threshold current magnitude; and
a detector coupled to the bidirectional ESD element, wherein the detector is configured to determine a state of the fuse.

2. The apparatus of claim 1, wherein the wire bond is coupled to the fuse by a dummy pad of the semiconductor package.

3. The apparatus of claim 1, wherein the ESD element includes a plurality of ESD diodes.

4. The apparatus of claim 3, wherein a first ESD diode of the plurality of ESD diodes is coupled to ground and a second ESD diode of the plurality of ESD diodes is coupled to the first ESD diode.

5. The apparatus of claim 1, wherein the detector includes a skewed driver.

6. The apparatus of claim 5, wherein the skewed driver is a weak pull-up and strong pull-down driver, or a strong pull-up and weak pull-down driver.

7. The apparatus of claim 1, wherein the ESD element includes a plurality of ESD snapback elements.

8. A semiconductor package, comprising:
a plurality of input/output (I/O) pads each coupled to a respective memory device;
a plurality of dummy pads;
a plurality of first electrostatic discharge (ESD) detection circuits, wherein each first ESD detection circuit is coupled to a respective I/O pad of the plurality of I/O pads; and
a plurality of second ESD detection circuits, wherein each second ESD detection circuit is coupled to a respective dummy pad of the plurality of dummy pads and configured to detect an ESD event associated with the respective dummy pad and a material external to the respective dummy pad.

9. The semiconductor package of claim 8, wherein each second ESD detection circuit comprises:
a respective fuse coupled between a bidirectional ESD element;
wherein the respective fuse is configured to receive an ESD discharge current generated between a wire bond coupled to the respective dummy pad and the material external to the semiconductor package; and
wherein the respective fuse is configured to blow in response to the ESD discharge current exceeding a threshold current magnitude; and
a respective detector coupled to the bidirectional ESD element, wherein the respective detector is configured to determine a state of the respective fuse.

10. The semiconductor package of claim 9, wherein the respective detector is configured to indicate a pass signal to a testing device in response to the respective fuse being intact and indicate a fail signal to the testing device in response to the respective fuse being blown.

11. The semiconductor package of claim 8, wherein the plurality of I/O pads, the plurality of dummy pads, the plurality of first ESD detection circuits, and the plurality of second ESD detection circuits are formed on a plurality of memory dies; and
wherein each memory die of the plurality of memory dies includes more than one dummy pad and more than one I/O pad.

12. The semiconductor package of claim 11, wherein a first memory die of the plurality of memory dies includes:
a first dummy pad coupled to a first pinout from the semiconductor package; and
a first I/O pad coupled to a second pinout from semiconductor package;
wherein a second memory die of the plurality of memory dies includes:
a second dummy pad coupled to the first dummy pad via a first wire bond; and
a second I/O pad coupled to the first I/O pad via a second wire bond; and
wherein a third memory die of the plurality of memory dies includes a third I/O pad coupled to the second dummy pad via a third wire bond.

13. The semiconductor package of claim 12, wherein the semiconductor package is configured to:
transfer data from the third I/O pad via the first and the second dummy pads to the first pinout; and
transfer data from the first I/O pad and the second I/O pad via the second pinout.

14. The semiconductor package of claim 11, wherein a first memory die of the plurality of memory dies includes:
a first dummy pad coupled to a first pinout from the semiconductor package; and
a first I/O pad;
wherein a second memory die of the plurality of memory dies includes:
a second dummy pad coupled to the first dummy pad via a first wire bond; and
a second I/O pad; and
wherein a third memory die of the plurality of memory dies includes:
a third dummy pad coupled to the second dummy pad via a second wire bond; and
a third I/O pad.

15. The semiconductor package of claim 14, wherein the semiconductor package comprises an engineering evaluation tool without functional data transfer from the first, second, or third I/O pads.

16. The semiconductor package of claim 14, wherein each second ESD detection circuit is configured to detect the ESD event in response to an ESD discharge current exceeding a threshold current magnitude.

17. The semiconductor package of claim 16, wherein the first memory die further includes a fourth dummy pad coupled to a second pinout from the semiconductor package;
wherein the second memory die further includes a fifth dummy pad coupled to the fourth dummy pad via third wire bond; and
wherein each second ESD detection circuit is configured to detect a single ESD event in response to the ESD discharge current exceeding the threshold current magnitude; and
wherein each second ESD detection circuit is configured to detect an ESD event with twice the threshold current magnitude in response to the ESD discharge current exceeding twice the threshold current magnitude.

18. A method, comprising:
routing, by electrostatic discharge (ESD) detection circuitry, a current through a fuse;
determining, by fuse detection circuitry, a state of the fuse;
refraining, by the ESD detection circuitry, from routing the current to an input/output (I/O) line in response to determining, by the fuse detection circuitry, that the fuse is in a blown state; and
routing, by the ESD detection circuitry, the current to the I/O line in response to determining, by the fuse detection circuitry, that the fuse is in an intact state.

19. The method of claim 18, further comprising:
receiving, by a first dummy pad of a memory die, a first current from a first I/O pin; and
receiving, by a second dummy pad of the memory die, a second current from a second I/O pin.

20. The method of claim 19, wherein a current that is lower than a threshold current is used to determine the state of the fuse and the fuse enters the blown state in response to the fuse receiving a current higher than the threshold amount of current.
